(19) United States
(12) Patent Application Publication
(10) Pub. No.: US 2002/0158708 A1
(43) Pub. Date: Oct. 31, 2002

(54) Surface acoustic wave filter, package for surface acoustic wave filter and surface acoustic wave filter module

(76) Inventors: Kenji Inoue, Tokyo (JP); Masahiro Nakano, Tokyo (JP)

Correspondence Address: BROWN RAYSMAN MILLSTEIN FELDER & STEINER, LLP, SUITE 711, 1880 CENTURY PARK EAST, LOS ANGELES, CA, 90067, US

(21) Appl. No.: 10/134,180

(22) Filed: Apr. 25, 2002

(30) Foreign Application Priority Data
Apr. 27, 2001 (JP) 2001-132588

(51) Int. Cl. H03H 9/64

(52) U.S. Cl. 333/133; 333/193

(57) ABSTRACT

One of the object of the present invention is to provide a surface acoustic wave filter can obtain a sufficient attenuation in the elimination band while it is mounted on the face down type package.

The surface acoustic wave filter of the present invention includes input/output electrodes, ground electrodes, a first resonator provided between the input/output electrodes, a second resonator provided between the input/output electrodes and the ground electrodes, and a capacitor pattern provided between the input/output electrodes and the ground electrodes. According to the present invention, a sufficient attenuation in the elimination band can be obtained, even though the inductance caused by the bonding wires is not added to the input/output electrodes. For this reason, small package can be used while high performance is obtained.

### BACKGROUND OF THE INVENTION

This invention relates to a surface acoustic wave filter, a package for the surface acoustic wave filter and a surface acoustic wave filter module, and particularly, to a surface acoustic wave filter, a package for the surface acoustic wave filter and a surface acoustic wave filter module that is suitable for applying to a duplexer.

### DESCRIPTION OF THE PRIOR ART

In recent years, mobile communication terminals inclusive of cellular telephones has been rapidly popularized. It is highly desirable to reduce this kind of terminals in size and weight for enhanced portability.

In order to achieve size and weight reductions for the mobile communication terminals, electronic components used therewith, too, must be essentially reduced in size and weight. For this reason, surface acoustic wave filter favorable for size and weight reduction, namely, surface acoustic wave filters are often used for high- and intermediate-frequency parts of the mobile communication terminals. The surface acoustic wave filter has an inter-digital electrode formed on a piezoelectric substrate, and for the purpose of preventing the corrosion of such inter-digital electrode, it is generally mounted and sealed in the package.

FIGS. 1 and 2 are a schematic sectional view showing the package 1 and 2 in which the surface acoustic wave filter is mounted, respectively.

The package 1 shown in FIG. 1 is a package of a type which establishes an electric connection to the surface acoustic wave filter 3 by the bonding wires 4; and the package 2 shown in FIG. 2 is a package of a type which establishes an electric connection to the surface acoustic wave filter 3 by the micro bumps 5. In the package 1 shown in FIG. 1, the surface acoustic wave filter 3 is placed such that the front surface 3a, on which an inter-digital electrode and input/output electrodes are formed, faces upward and the back surface 3b faces downward. On the contrary, in the package 2 shown in FIG. 2, the surface acoustic wave filter 3 is placed such that the back surface 3b faces upward and the front surface 3a faces downward. As the package 1 shown in FIG. 1, the package of the type which the surface acoustic wave filter 3 is placed such that the front surface 3a faces upward is called “face up type” package; and as the package 2 shown in FIG. 2, the package of the type which the surface acoustic wave filter 3 is placed such that the surface 3a faces downward is called “face down type” package.

In any packages shown in FIGS. 1 and 2, the external electrodes (not shown) are formed on its bottom, and when mounted on a motherboard, the electrical connection between the surface acoustic wave filter 3 and the electrode patterns formed on the motherboard is established via external electrodes.

In the face up type package 1 shown in FIG. 1, since a bonding wires 4 exist in electric circuit between an input/output electrodes (not shown) of the surface acoustic wave filter 3 and the external electrodes of the package 1, an inductance caused by the bonding wire 4 is added to the input/output electrodes of the surface acoustic wave filter 3. It is known that the inductance enhances the attenuation in the elimination band of the surface acoustic wave filter 3 (refer to Japanese Patent Laid Open No. 10-93375).

However, as shown in FIG. 1, in the face up type package 1, since the space to store the bonding wires 4 in the package 1 is needed, there are disadvantages that its thickness tends to be thick and its dimension in plan view tends to be large.

On the other hands, in the face down type package 2 shown in FIG. 2, since the electrical connection to the surface acoustic wave filter 3 is made by the micro bumps 5, its thickness can be thin and its dimension in plan view can be small. In the face down type package 2, however, since the inductance caused by the bonding wires 4 cannot be obtained, it is possible that the attenuation in the elimination band of the surface acoustic wave filter 3 may be insufficient.

### SUMMARY OF THE INVENTION

It is therefore an object of the present invention to provide a surface acoustic wave filter can obtain a sufficient attenuation in the elimination band while it is mounted on the face down type package.

Another object of the present invention is to provide a package of the face down type for the surface acoustic wave filter can obtain a sufficient attenuation in the elimination band.

Further object of the present invention is to provide a small surface acoustic wave filter module, which is constituted of a surface acoustic wave filter and a package of the face down type equipped with the surface acoustic wave filter, can obtain a sufficient attenuation in the elimination band.

The above and other objects of the present invention can be accomplished by a surface acoustic wave filter comprising input/output electrodes, a ground electrode, a first resonator provided between the input/output electrodes, a second resonator provided between at least one of the input/output electrodes and the ground electrode, and a capacitor pattern provided between at least one of the input/output electrodes and the ground electrode.

According to the present invention, because the capacitor pattern is provided between at least one of the input/output electrodes and the ground electrode, a sufficient attenuation in the elimination band can be obtained, even though the inductance caused by the bonding wires is not added to the input/output electrodes. For this reason, small package can be used while high performance is obtained.

In a preferred aspect of the present invention, the capacitor pattern is an inter-digital electrode formed on a piezoelectric substrate.

In a further preferred aspect of the present invention, the surface acoustic wave filter further comprises micro bumps formed on the input/output electrodes and the ground electrode.

The above and other objects of the present invention can be also accomplished by a package of a face down type for a surface acoustic wave filter comprising a substrate on which the surface acoustic wave filter is to be mounted, the substrate having an input/output electrode, a ground electrode, and a capacitor pattern provided between the input/output electrode and the ground electrode.

According to the present invention, because the capacitor pattern is provided between the input/output electrode and the ground electrode in the package for the surface acoustic wave filter, a sufficient attenuation in the elimination band of the surface acoustic wave filter can be obtained. For this reason, a miniaturization of the package can be achieved while high performance is obtained.

In a preferred aspect of the present invention, the capacitor pattern is a planar pattern formed on the substrate.

In a further preferred aspect of the present invention, the capacitor pattern is an inter-digital electrode formed on the substrate.

In another preferred aspect of the present invention, the capacitor pattern is a three dimensional pattern incorporated into the substrate.

The above and other objects of the present invention can be also accomplished by a surface acoustic wave filter module including a surface acoustic wave filter and a package on which the surface acoustic wave filter is mounted, comprising an input/output electrode, a ground electrode, and a capacitor pattern provided between the input/output electrode and the ground electrode.

Also according to the present invention, because the capacitor pattern is provided between the input/output electrode and the ground electrode, a sufficient attenuation in the elimination band of the surface acoustic wave filter can be obtained. For this reason, a miniaturization of the package can be achieved while high performance is obtained.

In a preferred aspect of the present invention, the surface acoustic wave filter includes a filter for transmitting and a filter for receiving so that the surface acoustic wave filter can be used as a duplexer.

In a further preferred aspect of the present invention, the package contains a multilayered substrate in which a branching line is incorporated.

In a further preferred aspect of the present invention, the package is a face down type package.

The above and other objects and features of the present invention will become apparent from the following description made with reference to the accompanying drawings.

### BRIEF DESCRIPTION OF THE DRAWINGS

FIG. 1 is a schematic sectional view showing the conventional package of a face up type for a surface acoustic wave filter.

FIG. 2 is a schematic sectional view showing the conventional package of a face down type for a surface acoustic wave filter.

FIG. 3 is a schematic plan view showing a surface acoustic wave filter 10 that is a further preferred embodiment of the present invention.

FIG. 4 is a plan view showing the structure of the pattern of resonators 12-17 in detail.

FIG. 5 is a plan view showing the structure of the capacitor patterns 24 and 25 in detail.

FIG. 6 is an equivalent circuit diagram of surface acoustic wave filter 10.

FIG. 7 is schematic block diagram showing the duplexer.

FIG. 8 is a schematic graph showing the frequency-response of the duplexer.

FIG. 9 is a schematic sectional view showing the surface acoustic wave filter module 45.

FIG. 10 is an equivalent circuit diagram of the surface acoustic wave filter module 45.

FIG. 11 is a graph showing the frequency-response of the surface acoustic wave filter 45.

FIG. 12 is a graph showing the frequency-response when the capacitor patterns 24 and 25 are eliminated from the surface acoustic wave filter 10 which is included in the surface acoustic wave filter 45.

FIG. 13 is a exploded schematic perspective view showing the surface acoustic wave filter module 50 that is another preferred embodiment of the present invention.

FIG. 14 is an equivalent circuit diagram of the surface acoustic wave filter module 50.

FIG. 15 is a exploded schematic perspective view showing the surface acoustic wave filter module 60 that is the further preferred embodiment of the present invention.

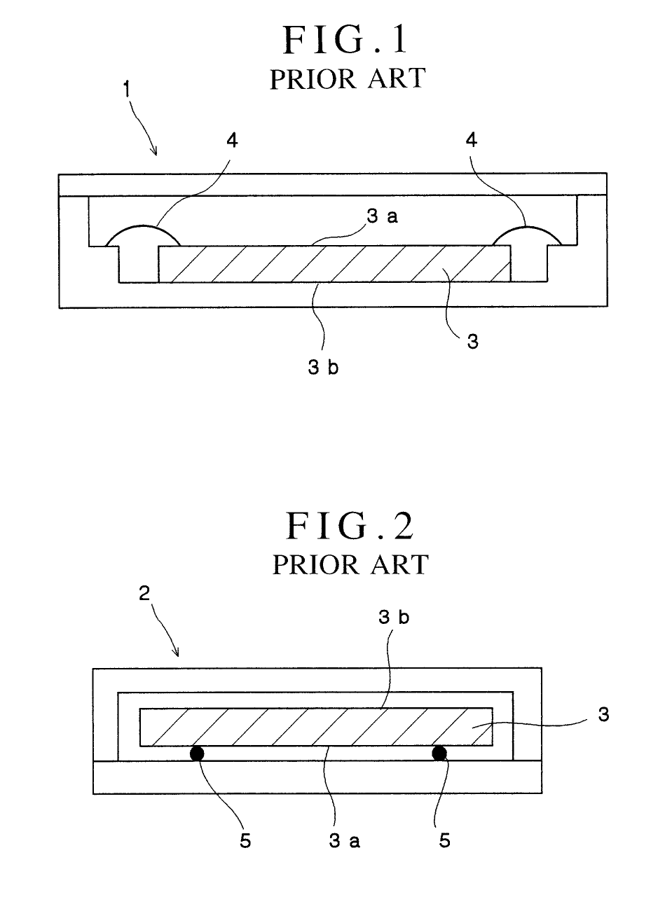

### DESCRIPTION OF THE PREFERRED EMBODIMENT

Preferred embodiments of the present invention will now be explained with reference to the drawings.

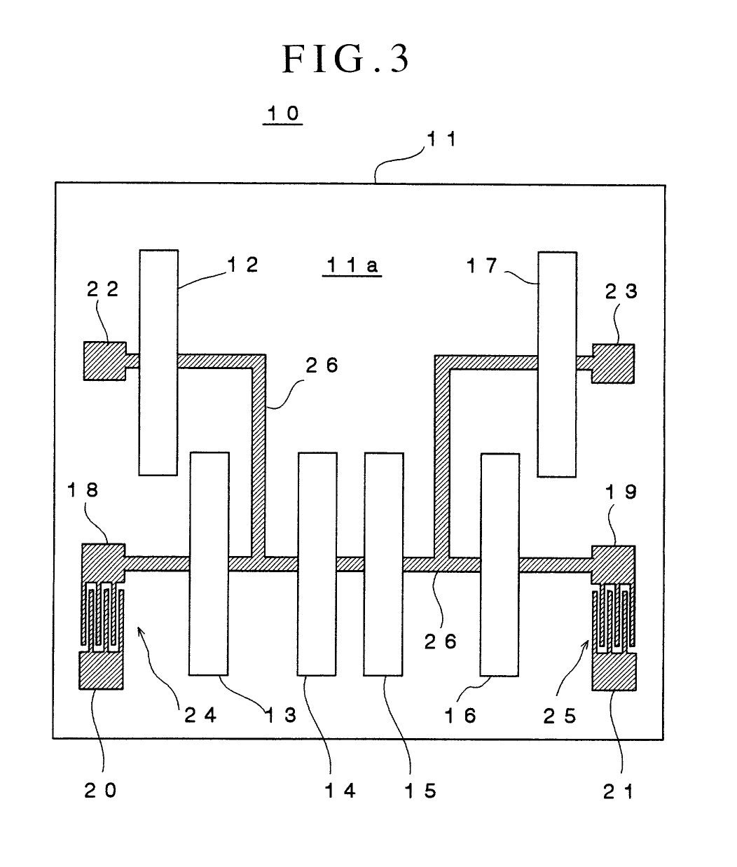

FIG. 3 is a schematic plan view showing a surface acoustic wave filter 10 that is a further preferred embodiment of the present invention.

As shown in FIG. 3, the surface acoustic wave filter 10 of this embodiment employs the resonators 12-17, input/output electrodes 18 and 19, ground electrodes 20-23, the capacitor patterns 24 and 25, and the wiring pattern 26 which connects above mentioned elements formed on the front surface 11a of the piezoelectric substrate 11. It is not especially limited, but as for the piezoelectric substrate 11, 39LT substrate, 128LN substrate, 64LN substrate, 36LT substrate, 112 LT substrate, ST crystal substrate, CTGS substrate, SNGS substrate, etc. can be used.

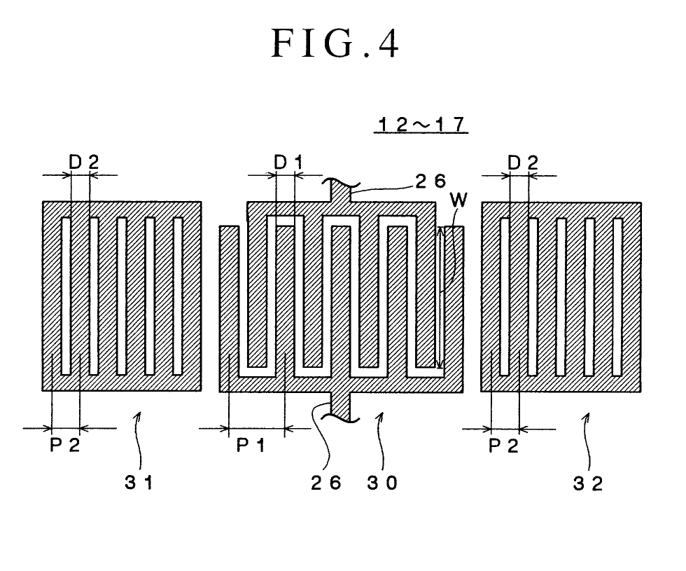

FIG. 4 is a plan view showing the structure of the pattern of resonators 12-17 in detail.

As shown in FIG. 4, the each resonator 12-17 include the inter-digital electrode 30 and the reflectors 31 and 32 disposed at the both side of the inter-digital electrode 30. The width of electrode fingers W, the electrode width D1, and the electrode finger pitch P1 of the inter-digital electrode 30 are determined according to a desired resonant characteristic for the resonators 12-17. The electrode width D2 and the electrode pitch P2 of the reflectors 31 and 32 are determined according to a desired resonant characteristic for the resonators 12-17.

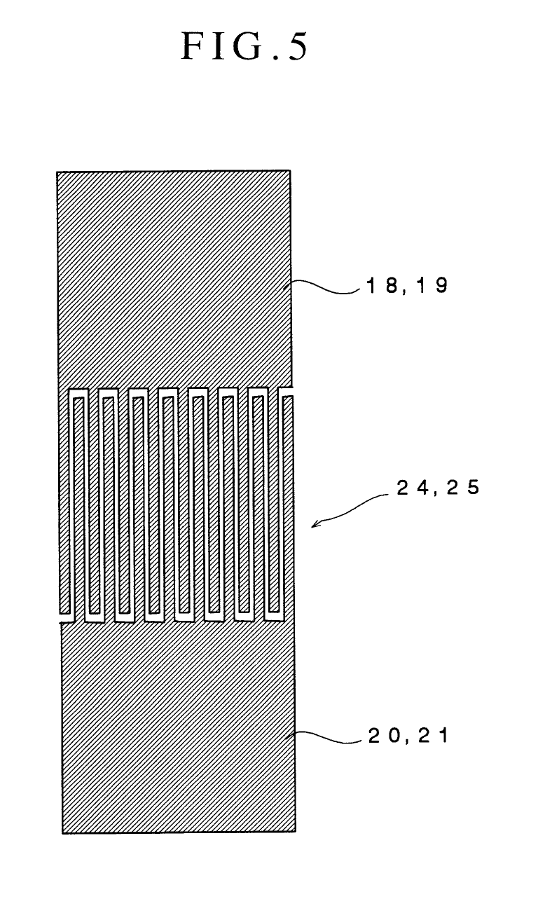

FIG. 5 is a plan view showing the structure of the capacitor patterns 24 and 25 in detail.

As shown in FIG. 5, each capacitor patterns 24 and 25 comprise the inter-digital electrodes, one of which is elongated from the input/output electrodes 18 and 19, respectively, and the other of which is elongated from the ground electrodes 20 and 21, respectively. It is not especially limited, but as for the capacitance of each capacitor patterns 24 and 25 is about 0.5 pF.

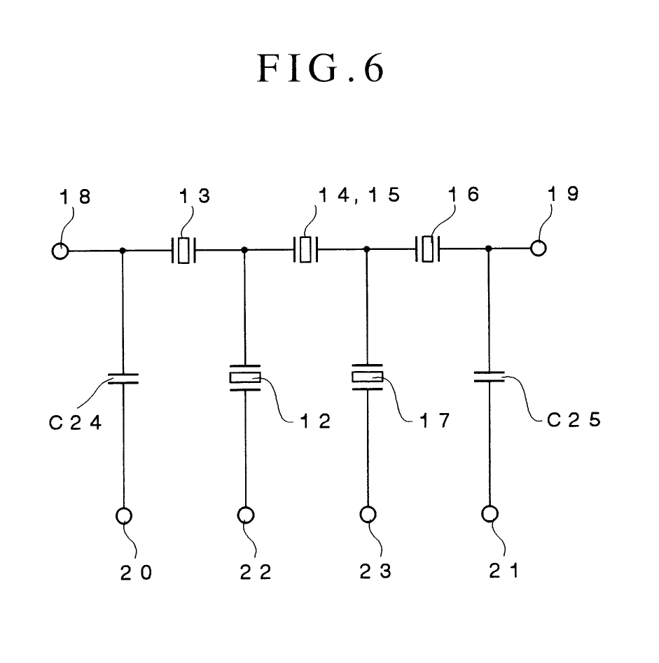

FIG. 6 is an equivalent circuit diagram of surface acoustic wave filter 10.

As shown in FIG. 6, in the surface acoustic wave filter 10 of this embodiment, resonators 13-16 works as a serial arm and resonators 17 and 18 works as a parallel arm. It is worth noting that the resonators 14 and 15 are shown as one resonator in FIG. 6. The capacitor C24 caused by the capacitor pattern 24 is connected between the input/output electrode 18 and the ground electrode 20, and the capacitor C25 caused by the capacitor pattern 25 is connected between the input/output electrode 19 and the ground electrode 21.

The surface acoustic wave filter 10 having above described configuration is called “a ladder type surface acoustic wave filter.” It is not especially limited, but the surface acoustic wave filter 10 is suitable to use as a duplexer used in the mobile communication terminals of a CDMA (Code Division Multiple Access) system.

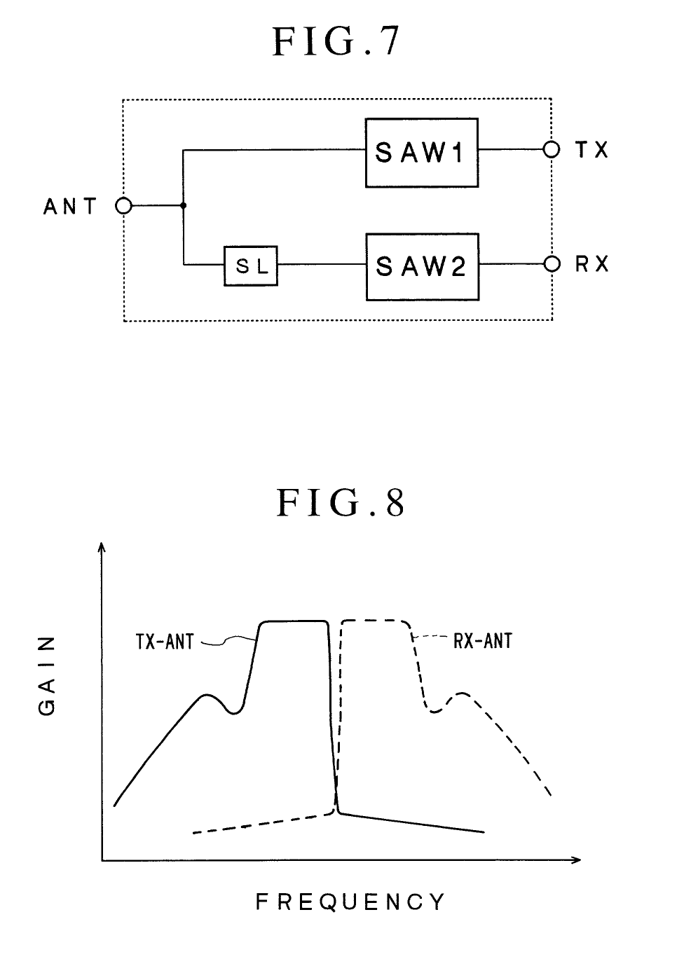

FIG. 7 is schematic block diagram showing the duplexer used in the mobile communication terminals.

As shown in FIG. 7, this kind of duplexer comprises a surface acoustic wave filter of transmitting side (SAW1) connected between an antenna terminal (ANT) and a transmitting terminal (TX), a branching line (SL) and a surface acoustic wave filter of receiving side (SAW2) connected in series between the antenna terminal (ANT) and a receiving terminal (RX).

FIG. 8 is a schematic graph showing the frequency-response of this kind of duplexer.

As shown in FIG. 8, in this kind of duplexer, a pass-band of the surface acoustic wave filter of transmitting side (SAW1) and a pass-band of the surface acoustic wave filter of receiving side (SAW2) are extremely approximate. For this reason, in the elimination band of the surface acoustic wave filter of transmission side (SAW1), the very large attenuation is required in the high side of the passing band which is close to the passing band of the surface acoustic wave filter of receiving side (SAW2). Similarly, in the elimination band of the surface acoustic wave filter of receiving side (SAW2), the very large attenuation is required in the low side of the passing band which is close to the passing band of the surface acoustic wave filter of transmitting side (SAW1).

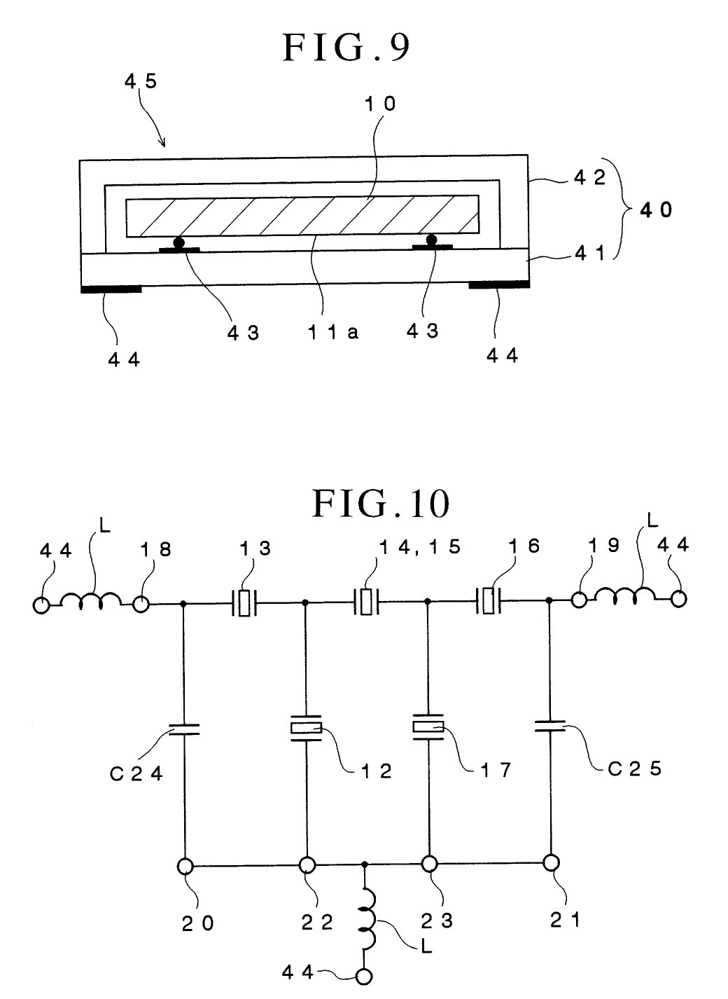

FIG. 9 is a schematic sectional view showing the surface acoustic wave filter module 45 which employs the surface acoustic wave filter 10 of this embodiment mounted on the package 40.

As shown in FIG. 9, the package 40 for the surface acoustic wave filter is a face down type package and comprises a multilayered substrate 41 and a cover element 42. A plurality of electrodes 43 are formed on the one surface of the multilayered substrate 41; and a plurality of electrodes 44 are formed on the other surface of the same. The electrodes 43 are the electrodes to be connected to the micro bumps which is formed on the electrodes 18-23 of the surface acoustic wave filter 10; and the electrodes 44 are the electrodes to be connected to the electrode patterns formed on the motherboard when the module 45 is mounted on a motherboard. Each electrode 43 and corresponding electrode 44 are electrically connected by the conductive pattern and through hole electrode (neither is shown) which are formed inside of the multilayered substrate 41.

FIG. 10 is an equivalent circuit diagram of the surface acoustic wave filter module 45.

As shown in FIG. 10, in the surface acoustic wave filter module 45, inductance L caused by the conductive pattern and through hole electrode which are formed inside of the multilayered substrate 41 is given between electrodes 18-23 formed on the surface acoustic wave filter 10 and corresponding electrodes 44 formed on the package 40 for the surface acoustic wave filter. However, since the package 40 for the surface acoustic wave filter is the face down type package, such inductance L is very small.

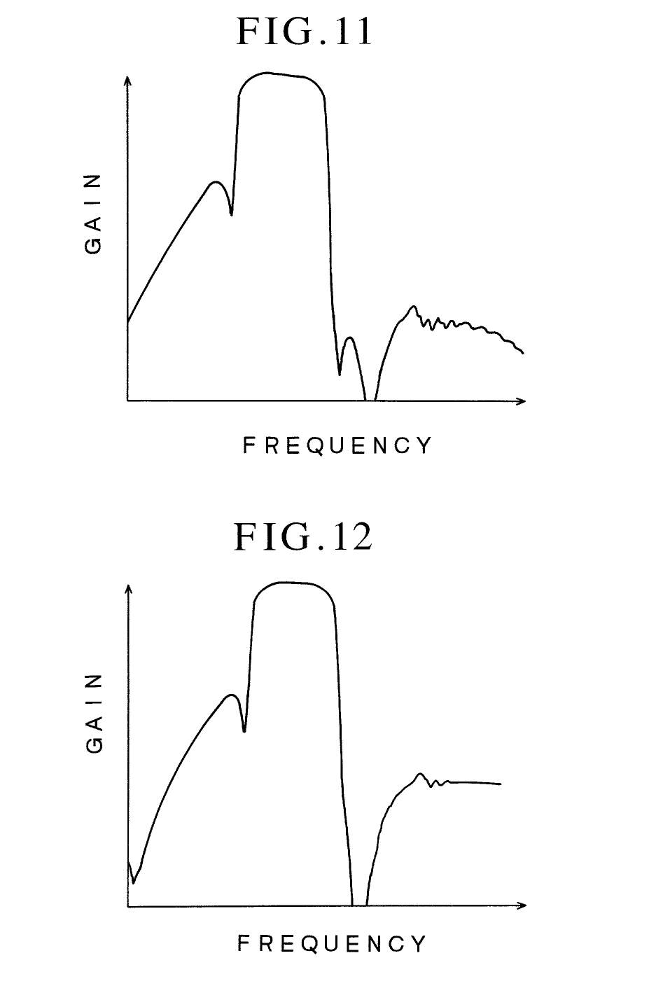

FIG. 11 is a graph showing the frequency-response of the surface acoustic wave filter module 45. FIG. 12 is a graph showing the frequency-response when the capacitor patterns 24 and 25 are eliminated from the surface acoustic wave filter 10 which is included in the surface acoustic wave filter module 45 as a comparative example.

As shown in FIG. 11, the surface acoustic wave filter module 45 employing the surface acoustic wave filter 10 of this embodiment can obtain larger attenuation of the high side elimination band than comparative example in which the capacitor patterns 24 and 25 are eliminated (FIG. 12). This means that the surface acoustic wave filter 10 of this embodiment is very suitable to use as a surface acoustic wave filter of transmitting side for duplexer (SAW1). Similarly, when the surface acoustic wave filter which can obtain very large attenuation of the low side elimination band is fabricated by adjusting the width of electrode fingers W, the electrode width D1 and D2, the electrode finger pitch P1, and the electrode pitch P2 of each resonators 12-17, the attenuation of the low side elimination band can be increased caused by the capacitor patterns 24 and 25. Such surface acoustic wave filter is very suitable as a surface acoustic wave filter of receiving side for duplexer (SAW2).

Furthermore, when both the electrode pattern which acts as a surface acoustic wave filter of transmitting side (SAW1) and the electrode pattern which acts as a surface acoustic wave filter of receiving side (SAW2) are formed on the front surface 11a of the piezoelectric substrate 11, and the branching line (SL) is formed by the conductive pattern in the multilayered substrate 41, it is possible to compose duplexer in one module. In this case, because, in the surface acoustic wave filer of transmitting side (SAW1), the attenuation of the high side elimination band which is the passing band of the surface acoustic wave filer of receiving side (SAW2) becomes extremely large, and in the surface acoustic wave filer of receiving side (SAW2), the attenuation of the low side elimination band which is the passing band of the surface acoustic wave filer of transmitting side (SAW1) becomes extremely large, the duplexer with very good characteristic can be obtained.

As described above, because the surface acoustic wave filter 10 of this embodiment employs capacitor patterns 24 and 25 formed on the front surface 11a of the piezoelectric substrate 11, large attenuation in the elimination band can be obtained even though it is mounted on the face down type package. For this reason, a small package can be used while high performance is obtained.

The equivalent effect caused by the capacitor patterns 24 and 25 can be obtained by enlarging the width of electrode fingers W of the inter-digital electrode 30 of the resonators 12 and 17 and by increasing the number of electrodes of the inter-digital electrode 30 so as to increase the capacitance of the resonators 12 and 17. However, in this case, the area of the piezoelectric substrate 11 should be increased greatly because the area occupied by the resonators 12 and 17 is increased. In view of foregoing, adding at least a part of capacitance between the input/output terminals 18 and 19 and the ground electrodes 20 and 21 by the capacitor patterns 24 and 25, it is possible to obtain the above-mentioned effect without increasing the area of the piezoelectric substrate 11.

Next, other preferred embodiment of the present invention will now be explained.

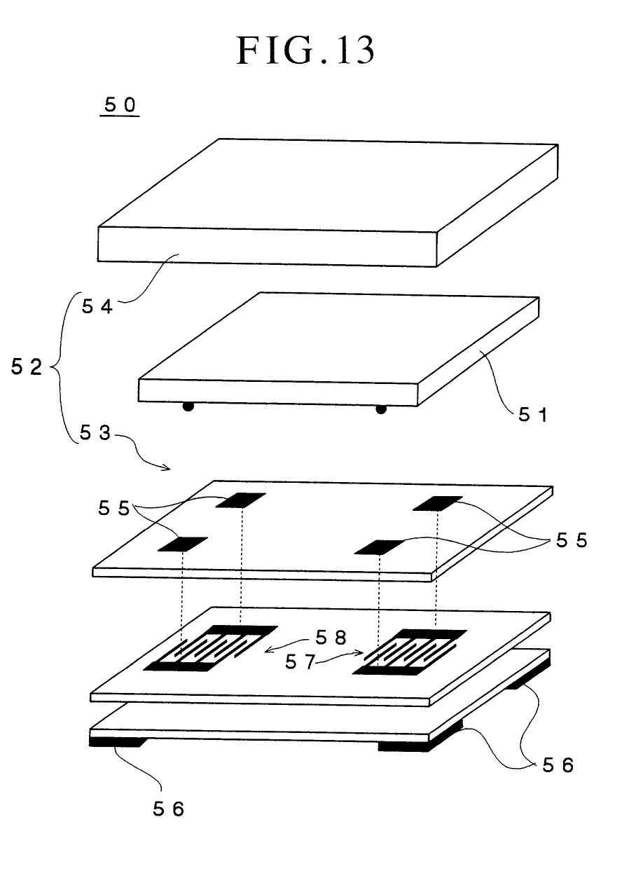

FIG. 13 is a exploded schematic perspective view showing the surface acoustic wave filter module 50 that is another preferred embodiment of the present invention.

As shown in FIG. 13, the surface acoustic wave filter module 50 of this embodiment comprises the surface acoustic wave filter 51 and the package 52 for the surface acoustic wave filter. The surface acoustic wave filter 51 has the structure that the capacitor patterns 24 and 25 which are employed in the surface acoustic wave filter 10 are deleted. The package 52 for the surface acoustic wave filter is the face down type package as same as the package 40 for the acoustic wave filter, and comprises the multilayered substrate 53 and the cover element 54. A plurality of electrodes 55 are formed on the one surface of the multilayered substrate 53, and a plurality of electrodes 56 are formed on the other surface of the same.

Moreover, the capacitor patterns 57 and 58 is formed inside of the multilayered substrate 53. The capacitor patterns 57 and 58 comprise the inter-digital electrodes, one of which is elongated from the input/output electrodes, and the other of which is elongated from the ground electrodes, similar to the capacitor patterns 24 and 25 mentioned above. The capacitance is given between the input/output electrodes and the ground electrodes, caused by the capacitor patterns 57 and 58.

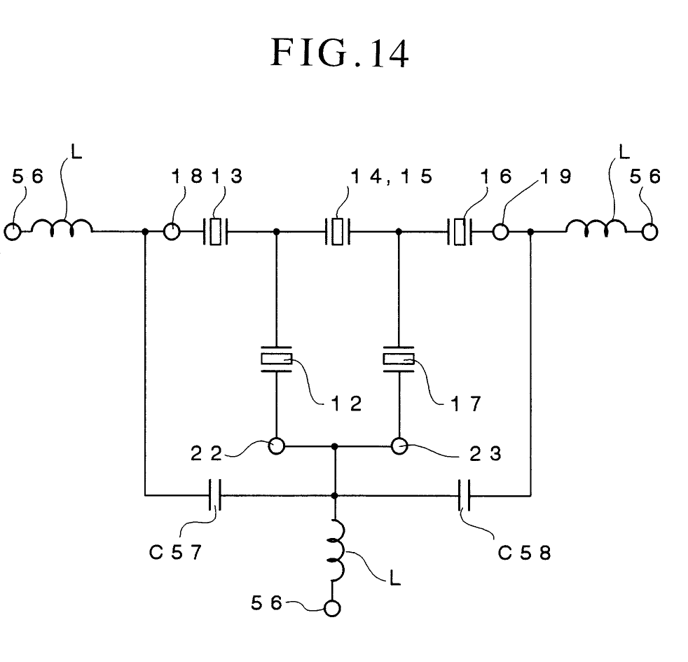

FIG. 14 is an equivalent circuit diagram of the surface acoustic wave filter module 50.

As shown in FIG. 14, in the surface acoustic wave filter module 50, the inductance L caused by conductive pattern and through hole element which are formed inside of the multilayered substrate 53 is given between the electrodes formed on the surface acoustic wave filter 51 and corresponding electrodes formed on the package 52. However, since the package 52 is the face down type package, such inductance element L is extremely small.

According to this embodiment, because the capacitance is added caused by the capacitor patterns 57 and 58 formed inside of the package 52 on which the surface acoustic wave filter 51 without employing the capacitor patterns 24 and 25 is mounted, large attenuation in the elimination band can be obtained even though the surface acoustic wave filter 51 does not employs the capacitor patterns 24 and 25. For this reason, a miniaturization of the package can be achieved while high performance is obtained.

Next, further preferred embodiment of the present invention will now be explained.

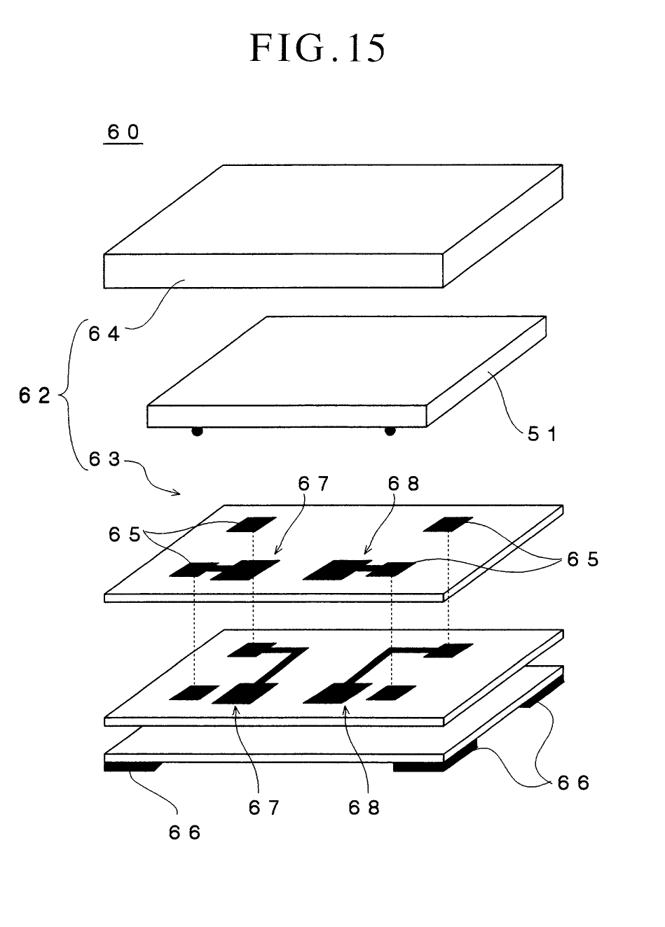

FIG. 15 is a exploded schematic perspective view showing the surface acoustic wave filter module 60 that is the further preferred embodiment of the present invention.

As shown in FIG. 15, the surface acoustic wave filter module 60 comprises the surface acoustic wave filter 51 and the package 62 for the surface acoustic wave filter. As mentioned above, the surface acoustic wave filter 51 has the structure that the capacitor patterns 24 and 25 which are employed in the surface acoustic wave filter 10 are deleted. The package 62 for the surface acoustic wave filter is the face down type package, as same as the packages 40 and 52 for acoustic wave filter, and comprises the multilayered substrate 63 and the cover element 64. A plurality of electrodes 65 are formed on the one surface of the multilayered substrate 63, and a plurality of electrodes 66 are formed on the other surface of the same.

Moreover, inside of the multilayered substrate 63, the capacitor patterns 67 and 68 are formed. The capacitor patterns 67 and 68 comprise the capacitor electrode, formed on the certain layer of the multilayered substrate 63, and the capacitor electrode formed on the other layer of the multilayered substrate 63, which are different from the capacitor patterns 57 and 58 formed on the package 52 for the surface acoustic wave filter of above mentioned embodiment. For this reason, the capacitance is added between the input/output electrodes and the ground electrodes.

The equivalent circuit diagram of the surface acoustic wave filter module 60 of this embodiment is the same equivalent circuit diagram with the surface acoustic wave filter module 50 shown in FIG. 14.

According to this embodiment, because the capacitance is added caused by the capacitor patterns 67 and 68 formed inside of the package 62 on which the surface acoustic wave filter 51 without employing the capacitor patterns 24 and 25 is mounted, large attenuation in the elimination band can be obtained even though the surface acoustic wave filter 51 does not employs the capacitor patterns 24 and 25. For this reason, a miniaturization of the package can be also achieved while high performance is obtained.

The present invention has thus been shown and described with reference to specific embodiments. However, it should be noted that the present invention is in no way limited to the details of the described arrangements but changes and modifications may be made without departing from the scope of the appended claims.

For example, the surface acoustic wave filter module 45 employs the capacitor patterns 24 and 25 formed on the surface acoustic wave filter 10 itself, and the surface acoustic wave filter modules 50 and 60 employ the capacitor patterns 57, 58, 67 and 68 formed in the packages 52 and 62 for surface acoustic wave filter on which the surface acoustic wave filter 51 is mounted. However, such capacitor patterns can be formed on the both surface acoustic wave filter and the package for the surface acoustic wave filter on which the filter is mounted.

Furthermore, the surface acoustic wave filter module 50 employs the capacitor patterns 57 and 58 of planar formed in of the multilayered substrate 53, and the surface acoustic wave filter module 60 employs the capacitor patterns 67 and 68 of three dimensional formed in the multilayered substrate 63. However, as a capacitor pattern formed in the multilayered substrate, it can be used both planar pattern and three dimensional pattern.

Moreover, although each surface acoustic wave filter module of above mentioned embodiments employs the surface acoustic wave filter of rudder type, the present invention is not limited to be applied to the surface acoustic wave filter of rudder type but can be applied to the surface acoustic wave filter of other type.

Furthermore, although the surface acoustic wave filter 10 of the above-mentioned embodiment employs the capacitor patterns 24 and 25 which are formed by the inter-digital electrodes, as a formation of the capacitor pattern, it is not limited to the inter-digital electrode, and it can be other formations.

As explained above, according to the present invention, because the capacitance is added between the input/output electrode and the ground electrode of the surface acoustic wave filter, a sufficient attenuation in the elimination band can be obtained, even though the inductance caused by the bonding wires is not added to the input/output electrodes.

1. A surface acoustic wave filter comprising input/output electrodes, a ground electrode, a first resonator provided between the input/output electrodes, a second resonator provided between at least one of the input/output electrodes and the ground electrode, and a capacitor pattern provided between at least one of the input/output electrodes and the ground electrode.

2. The surface acoustic wave filter as claimed in claim 1, wherein the capacitor pattern is an inter-digital electrode formed on a piezoelectric substrate.

3. The surface acoustic wave filter as claimed in claim 1, further comprising micro bumps formed on the input/output electrodes and the ground electrode.

4. The surface acoustic wave filter as claimed in claim 2, further comprising micro bumps formed on the input/output electrodes and the ground electrode.

5. A package of a face down type for a surface acoustic wave filter comprising a substrate on which the surface acoustic wave filter is to be mounted, the substrate having an input/output electrode, a ground electrode, and a capacitor pattern provided between the input/output electrode and the ground electrode.

6. The package for a surface acoustic wave filter as claimed in claim 5, wherein the capacitor pattern is a planar pattern formed on the substrate.

7. The package for a surface acoustic wave filter as claimed in claim 6, wherein the capacitor pattern is an inter-digital electrode formed on the substrate.

8. The package for a surface acoustic wave filter as claimed in claim 5, wherein the capacitor pattern is a three dimensional pattern incorporated into the substrate.

9. A surface acoustic wave filter module including a surface acoustic wave filter and a package on which the surface acoustic wave filter is mounted, comprising an input/output electrode, a ground electrode, and a capacitor pattern provided between the input/output electrode and the ground electrode.

10. The surface acoustic wave filter module as claimed in claim 9, wherein the surface acoustic wave filter includes a filter for transmitting and a filter for receiving so that the surface acoustic wave filter can be used as a duplexer.

11. The surface acoustic wave filter module as claimed in claim 10, wherein the package contains a multilayered substrate in which a branching line is incorporated.

12. The surface acoustic wave filter module as claimed in claim 9, wherein the package is a face down type package.

13. The surface acoustic wave filter module as claimed in claim 10, wherein the package is a face down type package.

14. The surface acoustic wave filter module as claimed in claim 11, wherein the package is a face down type package.
